(19) United States
(12) Patent Application Publication
(10) Pub. No.: US 2002/0061625 A1
(43) Pub. Date: May 23, 2002

(54) Method of manufacturing a metal oxide semiconductor device

(76) Inventors: Jyh-Ming Wang, Hsinchu Hsien (TW); Kun-Yuan Liao, Taichung Hsien (TW)

Correspondence Address: J.C. PATENTS INC., 4 VENTURE, SUITE 250, IRVINE, CA, 92618, US

(21) Appl. No.: 09/729,544

(22) Filed: Dec. 4, 2000

(30) Foreign Application Priority Data
Nov. 23, 2000 (TW) 89124862

(51) Int. Cl. H01L 21/336

(52) U.S. Cl. 438/301; 438/303; 438/306

(57) ABSTRACT

A method of manufacturing a metal oxide semiconductor device, wherein a gate dielectric layer, a conductive layer and a patterned mask layer are successively formed on the substrate. Using the mask layer as a mask, the conductive layer is slant-etched and the remaining portion of the conductive layer becomes a spacer wall of a gate and between the two sides of the gate, and exposes a portion of the gate dielectric layer. The gate is located directly below the mask layer. Using the mask layer and the spacer wall as a mask, ion implantation is performed, thereby forming a source/drain region within the substrate between the two sidewalls of the spacer walls. An annealing process is performed. Using the mask layer as a mask to etch away the spacer wall, a lightly doped drain is formed with the substrate between the two sidewalls of the gate, thereby completing a MOS device.

### CROSS-REFERENCE TO RELATED APPLICATION

This application claims the priority benefit of Taiwan application serial no. 89124862, filed Nov. 23, 2000.

### BACKGROUND OF THE INVENTION

1. Field of the Invention

The present invention relates to a semiconductor process. More particularly, the present invention relates to a method of manufacturing a metal oxide semiconductor (MOS) device.

2. Description of the Related Art

The basic structure of a MOS device includes a substrate, a gate oxide, a gate and a source/drain region on the two sides of the gate within the substrate. The portion of the gate adjacent to the source/drain region often uses the technique of a lightly doped drain (LDD), thereby preventing a short channel effect. The manufacturing process of a MOS device in the related art includes forming a gate dielectric layer and gate successively on the substrate, and forming an LDD on the two sides of the gate within the substrate. A conformal silicon oxide layer is deposited on the substrate, anisotropic etching is used to etch the silicon oxide layer and a spacer wall is formed on the gate sidewall. A source/drain region is formed within the substrate on the two sides of the spacer wall and by performing an annealing process, the MOS device is completed.

Although the above-described related art technique has long been in use, however, following the semiconductor manufacturing dimension restricted to under 0.13 μm, this poses a problem. The width between the gates decreases as the gate dimensions are reduced and thereby causes the step coverage during deposition of the silicon oxide layer in the front portion of the spacer wall to be ineffective. Thus, the gap between the gates are filled and are no longer conformal to the substrate and gate. The above-described process is problematic in that since the silicon oxide layer is no longer conformal to the substrate and the gate, the silicon oxide layer thickness does not easily control the etching of the spacer wall and the spacer wall width is not as even. Another problem arising from the related art technique is that in order to form spacer walls separate from each other, the silicon oxide layer in the front portion of the spacer wall is over-etched during manufacturing, thereby causing damage to the gate and the source/drain region interface formed shortly thereafter. A third disadvantage to the related art technique is that even if the spacer wall can be successfully formed, the presence of the spacer wall cause the gap between the gates to be even narrower. Consequently, during deposition of the inter-layer dielectric (ILD) layer, a hole can be created easily and is harmful to the latter processes.

### SUMMARY OF THE INVENTION

The present invention provides a method of manufacturing a MOS device, wherein a gate dielectric layer, a conductive layer and a patterned mask layer are successively formed on the substrate. The mask layer is used as a mask to slant-etch the conductive layer, thereby making the remaining conductive layer into a gate and a spacer wall on one of the two sides and exposing a portion of the gate dielectric layer, wherein the gate is located directly below the mask. Using the mask layer and the spacer wall as a mask, ion implantation is performed, thereby forming a source/drain region on the two sides of the spacer wall within the substrate and an annealing process is performed. Using the masking layer as a mask to etch away the spacer wall, LDD is formed within the substrate on the two sides of the gate, thereby forming a MOS device.

As embodied and broadly described herein, the invention provides several advantages, wherein the present invention uses a slant-etching process to form a spacer wall on the two sides of a gate. Hence, the accuracy of the spacer wall contour and width is not as affected by the size and width of the gap between the gates. Another advantage of the present invention is that in forming the source/drain region and performing the annealing process and forming the LDD thereafter, the lateral diffusion of the LDD can be reduced and prevents the short channel effect from happening. A third advantage of the present invention is that the spacer wall is removed before the LDD is formed, therefore the width between the gates do not shrink, so that during the successive deposition of the ILD layer, no holes will be created.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention, and, together with the description, serve to explain the principles of the invention. In the drawings,

FIGS. 1A to 1E are diagrams illustrating a method of manufacturing a MOS device according to one preferred embodiment of the present invention.

### DESCRIPTION OF THE PREFERRED EMBODIMENTS

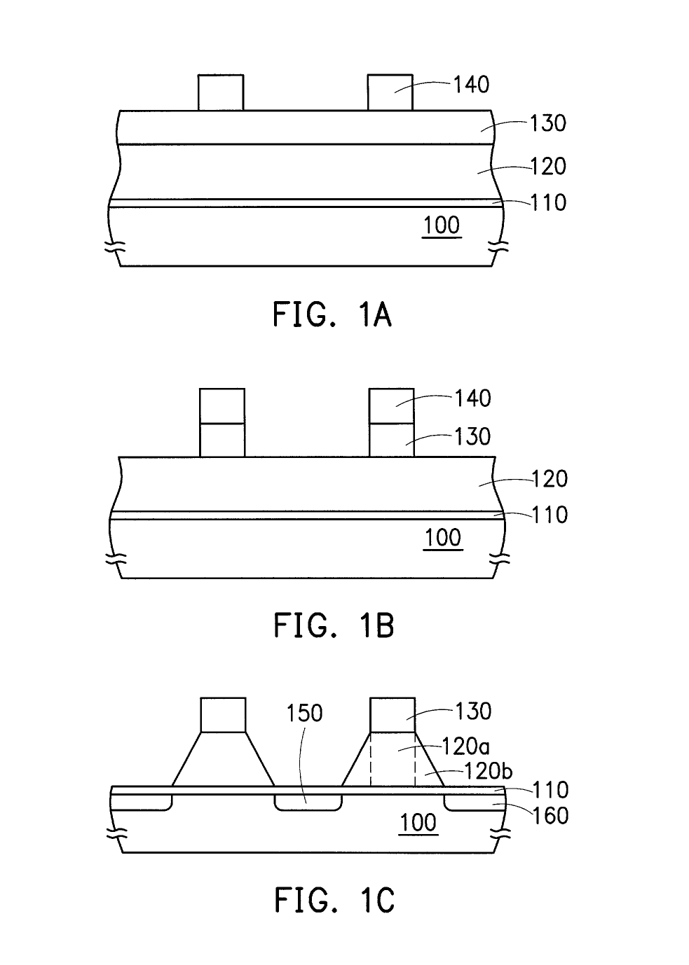

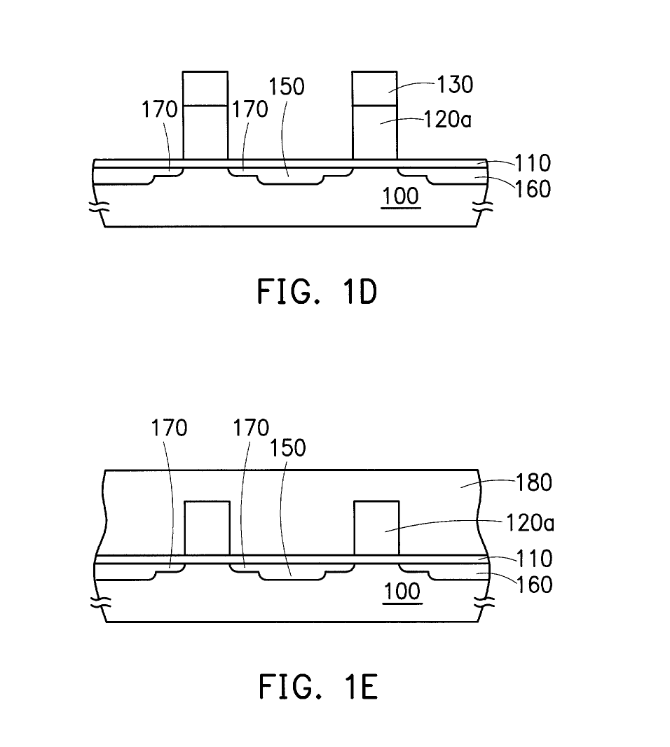

Refering to FIG. 1A, a substrate 100 is provided. A gate oxide layer 110, a polysilicon layer 120 and a hard mask layer 130 are successively formed upon the substrate 100. A gate-patterned photoresist layer 140 is formed on the hard mask layer 130. The gate oxide layer 110 thickness is less than 32 Å in order to meet the 0.13 μm manufacturing requirement. The polysilicon layer 120 becomes the front portion of the gate and has a thickness of about 2000 Å. The hard mask layer 130 can be a silicon oxide layer with a thickness of about 400 Å.

Referring to FIG. 1B, using the photoresist 140 as a mask, anisotropic etching is used to remove the exposed portion of the mask layer 130, and the gate pattern is moved onto the hard mask layer 130.

Referring to FIG. 1C, successively using the photoresist layer 140 and the hard mask layer 130 as a mask (the photoresist layer 140 is consumed during the etching process), the anisotropic etching process is used to slant-etch the polysilicon layer 120. The remaining polysilicon layer 120 becomes the gate 120a directly below the hard maks layer 130 and the polysilicon spacer wall 120b between the two sides of the gate 120a. The slant-etching process of the polysilicon layer 120 can be an adjusted etching gas formula, thereby forming a polymer on the exposed sidewalls of the polysilicon layer 120 during etching and using the blocking properties of the polymer to form a slanted sidewall. Referring to 1C, using the polysilicon spacer wall 120b and the hard mask layer 130 as a mask, ion implantation is performed. A common source region 150 is formed within the substrate 100 between the two polysilicon spacer walls 120b and thereby forming a drain region 160 within the substrate 100 on the other side of the polysilicon spacer wall 120b. An annealing process is performed, thereby restoring lattice structure of the common source region 150 and the drain region 160.

Referring to FIG. 1D, using the hard mask layer 130 as a mask, a dry etching process is used to remove the polysilicon spacer wall 120b. The etching gas used in the dry etching process is preferably mainly hydrogen bromide (HBr) and the bombardment capacity of the active ions is lower than what is most used during vertical etching. The reason is that when the ion bombardment capacity is low during etching, an inwardly slanted contour is facilitated and thus, contributes to the etching of the outwardly slanted wall of the remaining polysilicon layer (made up of the gate 120a and the polysilicon spacer wall 120b) into a vertical state.

Referring to FIG. 1D, using the hard mask layer 130 as a mask, ion implantation is performed, thereby forming a LDD 170 within the substrate 100 on each of the two sides of the gate 120a so as to complete the MOS device according to one preferred embodiment of the present invention.

Referring to FIG. 1D, the remaining hard mask layer 130 is removed. The ILD layer 180 covers the substrate and is made from a material such as silicon oxide in order to facilitate performing successive processes such as a contact window process and an upper layer internal circuit structure.

As described above, there are several advantages to the method of manufacturing a MOS device according to one preferred embodiment of the present invention. One advantage of the present invention is that the polysilicon spacer walls 120b on the two sides of the gate 120a are formed from slant-etching (see FIG. 1C), the contour and width of the spacer wall 120b are easily controlled and do not create an unevenness that may result due to a insufficient width in the gaps between the spacer walls 120b.

Another advantage of the present invention is that, as shown in FIG. 1C, during slant-etching of the polysilicon layer 120, a gate oxide layer 110 covers the predetermined region (so-called because the etching has not yet been completed) of the common source region 150/the drain region 160. Although the etching rate of the polysilicon and the silicon oxide is very high, the substrate 100 is protected as it lies below the gate oxide layer 110. Therefore, the interface of the common source region 150 and drain region 160 is prevented from damage.

A third advantage is that the formation of the common source region 150 and drain region 160 is performed prior to the formation of LDD 170 in the annealing process, so that the lateral diffusion of the LDD 170 is reduced and thus prevents the short channel effect from happening.

A fourth advantage of the present invention is that since the polysilicon spacer walls 120b are removed before the formation of the LDD 170, the width between the two gates 120a do not shrink. Hence, holes are not created during the deposition of the ILD layer 180 (see FIG. 1E), and do no block the subsequent contact windows and internal circuit processes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a metal oxide semiconductor (MOS) device suitable for use on a substrate, comprising:
successively forming a gate dielectric layer, a conductive layer and a patterned mask layer on the substrate;
using the mask layer as a mask, slant-etching the conductive layer, thereby making the remaining conductive layer into a gate and a spacer wall on one of the two sides and exposing a portion of the gate dielectric layer, wherein the gate is located directly below the mask;
using the mask layer and the spacer wall as a mask, ion implantation is performed, thereby forming a source/drain region on the two sides of the spacer wall within the substrate;
performing an annealing process, thereby restoring the lattice region of the source/drain region:
using the masking layer as a mask to etch away the spacer wall; and
forming LDD within the substrate on the two sides of the gate, thereby forming a MOS device

2. The method as defined in claim 1, wherein the source region is a common source region, the common source region is used by both the MOS device and another MOS device, and is formed on the substrate between the spacer wall and “the spacer wall of the other MOS device”.

3. The method as defined in claim 1, after formation of the lightly doped drain (LDD), further comprising:
completing the removal of the mask layer; and
covering an inter-layer dielectric (ILD) layer on the substrate, wherein the ILD layer is filled with gates and other gaps between the gates.

4. The method as defined in claim 3, wherein the ILD layer includes a silicon oxide layer.

5. The method as defined in claim 1, wherein the mask layer is a silicon oxide hard mask layer.

6. The method as defined in claim 5, wherein the thickness of the silicon oxide hard mask layer is about 400 Å.

7. The method as defined in claim 1, wherein the slant-etching process of the conductive layer for the formation of the gate and the spacer walls include using an etching gas to etch the conductive layer and the etching gas forms a polymer film on the exposed side of the conductive layer during etching, thereby becoming an etch block layer.

8. The method as defined in claim 1, wherein the etching gas used during the removal of the spacer wall includes hydrogen bromide (HBr).

9. The method as defined in claim 1, wherein the gate dielectric layer includes a gate oxide layer.

10. The method as defined in claim 9, wherein the thickness of the gate oxide layer is about 32 Å.

11. The method as defined in claim 1, wherein the conductive layer includes a polysilicon layer.

12. The method as defined in claim 11, wherein the thickness of the polysilicon layer is about 2000 Å.

13. A method of manufacturing a MOS device, suitable for use on a substrate, comprising:
successively forming a gate dielectric layer, a conductive layer and a patterned mask layer on a substrate, with two adjacent gate mask pattern therein;
using the mask layer as a mask to slant-etch the conductive layer, and making the remaining conductive layer into two spacer walls between two gates and two gate sidewalls, wherein a portion of the gate dielectric layer is exposed and the two gates are located directly below the gate mask pattern;
using the mask layer and the two spacer walls as a mask, ion implantation is performed and a source region is formed within the substrate between the two spacer walls, and a drain region is simultaneously formed within the substrate outside the two spacer walls;
performing an annealing process, thereby restoring the lattice structure of the common source region and the two drain regions;
using the mask as a mask, the two spacer walls are removed; and
forming a plurality of LDD within the substrate between the two gates and outside the two gates, thereby completing two MOS devices.

14. The method as defined in claim 13, after LDD formation, further comprising:
completely removing of the mask layer; and
covering an ILD layer on the substrate, wherein the ILD layer is filled with the gaps between the two gates.

15. The method as defined in claim 14, wherein the ILD layer includes a silicon layer.

16. The method as defined in claim 13, wherein the mask layer is a silicon oxide mask layer.

17. The method as defined in claim 13, wherein the slant-etching process of the conductive layer for the formation of the two gates and the two spacer walls includes using an etching gas to etch the conductive layer; the etching gas forms a polymer film on the sidewall of the conductive layer during etching, and thus becomes an etch block layer.

18. The method as defined in claim 13, wherein the etching gas used during the removal of the two spacer walls includes hydrogen bromide.

19. The method as defined in claim 13, wherein the gate dielectric layer includes a gate oxide layer.

20. The method as defined in claim 13, wherein the conductive layer includes a polysilicon layer.
